(19) United States
(12) Patent Application Publication
(10) Pub. No.: US 2020/0020827 A1
(43) Pub. Date: Jan. 16, 2020

(54) OPTICAL DEVICE AND METHOD OF MANUFACTURING THE SAME

(71) Applicant: Advanced Semiconductor Engineering, Inc., Kaohsiung (TW)

(72) Inventors: Hsin-Ying HO, Kaohsiung (TW); Ying-Chung CHEN, Kaohsiung (TW); Lu-Ming LAI, Kaohsiung (TW)

(73) Assignee: Advanced Semiconductor Engineering, Inc., Kaohsiung (TW)

(21) Appl. No.: 16/505,331

(22) Filed: Jul. 8, 2019

Related U.S. Application Data
(60) Provisional application No. 62/697,283, filed on Jul. 12, 2018.

(51) Int. Cl. H01L 33/08; H01L 33/10; H01L 33/26

(52) U.S. Cl. CPC H01L 33/08; H01L 33/0054; H01L 33/26; H01L 33/105

(57) ABSTRACT

An optical device includes a substrate, an electronic component, a lid and a barrier. The electronic component is disposed on the substrate. The electronic component has an active surface faces away from the substrate. The lid is disposed on the substrate. The lid has a wall structure extending toward the active surface of electronic component and is spaced apart from the active surface of the electronic component. The barrier is disposed on the active surface of the electronic component and is spaced apart from the wall structure of the lid.

### CROSS-REFERENCE TO RELATED APPLICATIONS

This application claims the benefit of and priority to U.S. Provisional Application No. 62/697,283, filed Jul. 12, 2018, the contents of which are incorporated herein by reference in their entirety.

### BACKGROUND

### 1. Technical Field

The present disclosure relates to an optical device, and more particularly to an optical device including a block structure.

### 2. Description of the Related Art

In an optical system (e.g., light scanning sensor, distance finding sensor, background-light sensing system), light emitters (e.g., vertical-cavity surface-emitting LASER (VCSEL) or light emitting diodes (LED)) and/or light detectors are used to detect whether any object is located adjacent to the optical system or an electronic component including the optical system. The light emitter is configured to emit light toward a target object, and the light reflected from the target object is received by the light detector. However, some of the light emitted from the light emitter may enter the light detector directly, which would cause an unacceptable cross-talk issue and reduce the signal-noise ratio (SNR) of the optical system.

### SUMMARY

In accordance with an aspect of the present disclosure, an optical device includes a substrate, an electronic component, a lid and a barrier. The electronic component is disposed on the substrate. The electronic component has an active surface faces away from the substrate. The lid is disposed on the substrate. The lid has a wall structure extending toward the active surface of electronic component and is spaced apart from the active surface of the electronic component. The barrier is disposed on the active surface of the electronic component and is spaced apart from the wall structure of the lid.

In accordance another aspect of the present disclosure, an optical device includes a substrate, an electronic component, a barrier and a lid. The electronic component is disposed on the substrate. The electronic component has an active surface facing away from the substrate. The barrier is disposed on the active surface of the electronic component. The lid is disposed on the substrate. The lid has a wall structure extending toward the active surface of electronic component and is spaced apart from the active surface of the electronic component. The barrier is spaced apart from the wall structure and adjacent to at least one lateral surface of the wall structure of the lid.

In accordance another aspect of the present disclosure, a method for manufacturing an optical device includes (a) providing a substrate; (b) disposing an electronic component on the substrate, the electronic component having an active surface facing away from the substrate; (c) disposing a barrier on the active surface of the electronic component; (d) removing a portion of the barrier to form a recess; and (e) placing a lid disposed on the substrate, the lid having a wall structure extending within the recess and spaced apart from a sidewall and a bottom surface of the recess.

### BRIEF DESCRIPTION OF THE DRAWINGS

FIG. 1A illustrates a cross-sectional view of an optical device in accordance with some embodiments of the present disclosure;

FIG. 1B illustrates a perspective view of the optical device in FIG. 1A in accordance with some embodiments of the present disclosure;

FIG. 2 illustrates a cross-sectional view of an optical device in accordance with some embodiments of the present disclosure;

FIG. 3 illustrates a cross-sectional view of an optical device in accordance with some embodiments of the present disclosure;

FIG. 4 illustrates a cross-sectional view of an optical device in accordance with some embodiments of the present disclosure;

FIG. 5A illustrates a cross-sectional view of an optical device in accordance with some embodiments of the present disclosure;

FIG. 5B illustrates an enlarged view of a portion of the optical device in FIG. 5A in accordance with some embodiments of the present disclosure;

FIG. 5C illustrates an enlarged view of a portion of the optical device in FIG. 5A in accordance with some embodiments of the present disclosure;

FIG. 6A, 6A′, 6B and FIG. 6C illustrate a method for manufacturing an optical system in accordance with some embodiments of the present disclosure;

Common reference numerals are used throughout the drawings and the detailed description to indicate the same or similar components. The present disclosure can be best understood from the following detailed description taken in conjunction with the accompanying drawings.

### DETAILED DESCRIPTION

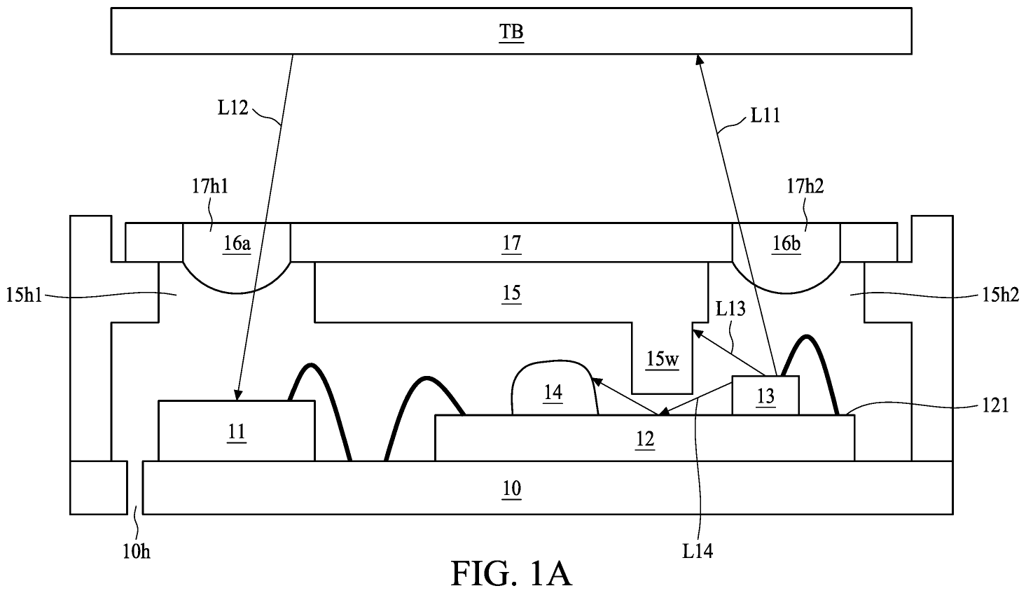

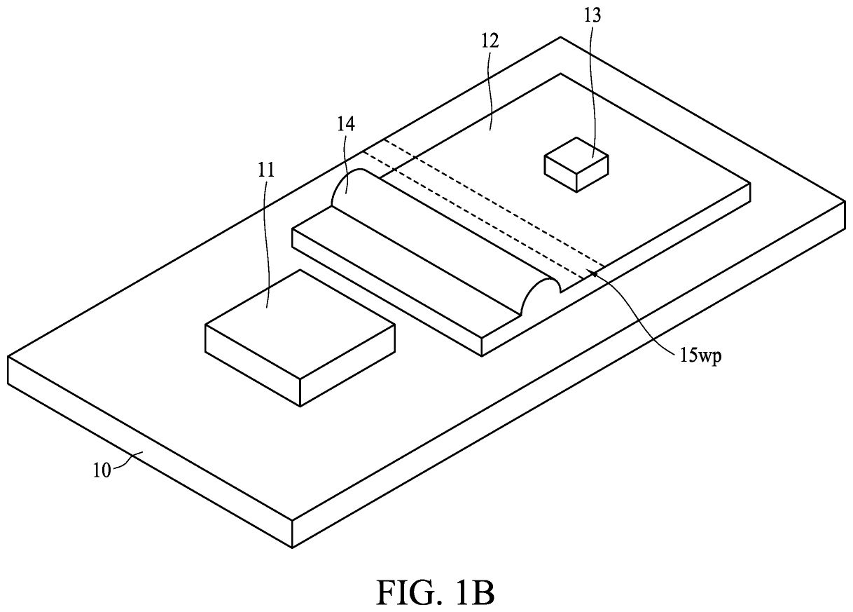

FIG. 1A illustrates a cross-sectional view of an optical device 1 in accordance with some embodiments of the present disclosure. The optical device 1 includes a substrate 10, a light detector 11, an electronic component 12, a light emitter 13, a barrier (a block structure or a dam) 14, a lid 15, lenses 16a, 16b and a cover 17. In some embodiments, the optical device 1 in FIG. 1A may be a light scanning sensor, a distance finding sensor, a background-light sensing system, a ToF sensor or the like.

The substrate 10 may include, for example, a printed circuit board, such as a paper-based copper foil laminate, a composite copper foil laminate, or a polymer-impregnated (p.p.) glass-fiber-based copper foil laminate. The substrate 10 may include an interconnection structure, such as a plurality of conductive traces, pads or through vias. In some embodiments, the substrate 10 includes a ceramic material or a metal plate. In some embodiments, the substrate 10 may include an organic substrate or a leadframe. In some embodiments, the substrate 10 may include a two-layer substrate which includes a core layer and a conductive material and/or structure disposed on an upper surface and a bottom surface of the substrate 10. The conductive material and/or structure may include a plurality of traces, pads, or vias. In some embodiments, the substrate 10 includes a hole 10h (e.g., a vent hole) penetrating the substrate 10 to vent the air within a cavity defined by the substrate 10, the lid 15 and the cover 17, which can mitigate or eliminate the popcorn issue.

The electronic component 12 (a die or a chip) is disposed on the substrate 10 and connected to the substrate 10 for example, by way of flip-chip or wire-bond techniques. In some embodiments, as shown in FIG. 1A, the electronic component 12 has an active surface 121 facing away from the substrate 10 and is connected to the substrate 10 by bonding wires. In some embodiments, the electronic component 12 may be or include a controller, a processor, a memory, an application-specific integrated circuit (ASIC) or the like.

The light emitter 13 is disposed on the electronic component 12. In some embodiments, the light emitter 13 is disposed on the active surface 121 of the electronic component 12 and can be electrically connected to the electronic component 12 by bonding wires. In some embodiments, the light emitter 13 is configured to radiate a light (e.g., L11) toward an object TB. The light emitter 13 may include an emitting die or other optical die. For example, the light emitter 13 may include a light-emitting diode (LED), a laser diode, a vertical-cavity surface-emitting Laser (VCSEL) or another device that may include one or more semiconductor layers. The semiconductor layers may include silicon, silicon carbide, gallium nitride, or any other semiconductor materials.

The light detector 11 is disposed on the substrate 10 and is physically separated from the light emitter 13 and the electronic component 12. In some embodiments, the light detector 11 has an active region (or light detecting area) facing away from the substrate 10 and configured to receive the light (e.g., L12) reflected from the object TB. In some embodiments, the light detector 11 may include, for example, a PIN diode (a diode including a p-type semiconductor region, an intrinsic semiconductor region, and an n-type semiconductor region) or a photo-diode or a photo-transistor. In some embodiments, the light detector 11 is an ambient light sensing (ALS). The light detector 11 can be connected to the substrate 10, for example, by way of flip-chip or wire-bond techniques.

The lid (or housing) 15 is disposed on the substrate 10. The lid 15 has a wall structure 15w extending from the lid 15 toward the electronic component 12. The wall structure 15w is disposed between the light detector 11 and the light emitter 13. The wall structure 15w is disposed over the electronic component 12. In some embodiments, the wall structure 15w is spaced apart from the active surface 121 the electronic component 12. For example, the wall structure 15w is not in contact with the active surface 121 of the electronic component 12. For example, there is a gap between the wall structure 15w and the active surface 121 of the electronic component 12. The lid 15 has an opaque material or a light absorbing material to prevent undesired light (e.g., L13) emitted by the light emitter 13 from being directly transmitted to the light detector 11.

The barrier 14 is disposed on the electronic component 12 (e.g., on the active surface 121 of the electronic component 12). The barrier 14 is in contact with the active surface 121 of the electronic component 12. In other embodiments, the barrier 14 may be in contact with the active surface 121 and lateral surfaces of the electronic component 12. The barrier 14 is spaced apart from the lid 15 and the wall structure 15w of the lid 15. For example, there is a gap between the barrier 14 and the lid 15 or between the barrier 14 and the wall structure 15w of the lid 15. The barrier 14 is disposed between the light emitter 13 and the light detector 11 and adjacent to the wall structure 15w of the lid 15. As shown in FIG. 1A, the barrier 14 is disposed between the light detector 11 and the wall structure 15w. In some embodiments, the barrier 14 can be disposed between the wall structure 15w and the light emitter 13. In some embodiments, the barrier 14 can be disposed at both sides of the wall structure 15w. For example, there are two barriers, one is disposed between the light emitter 13 and the wall structure 15w and the other is disposed between the wall structure 15w and the light detector 11.

As shown in FIG. 1B, which illustrates a perspective view of the optical device 1 in FIG. 1A (for clarity, the lid 15, the lens 16 and the cover 17 are omitted in FIG. 1B), the barrier 14 is disposed between the light detector 11 and the location 15wp of the electronic component 12 over which the wall structure 15w of the lid 15 is disposed. In some embodiments, the barrier 14 can be disposed between the light emitter 13 and the location 15wp. In some embodiments, the barrier 14 can be disposed at both sides of the location 15wp. For example, there are two barriers, one is disposed between the light detector 11 and the location 15wp and the other is disposed between the light emitter 13 and the location 15wp.

In some embodiments, the barrier 14 is formed of or includes an opaque material or light absorbing material. In some embodiments, a height of the barrier 14 is equal to or greater than a distance between the wall structure 15w and the active surface 121 of the electronic component 12. In some embodiments, a height of the barrier 14 is about 0.2 millimeter (mm) and a width of the barrier 14 is about 0.4 mm. In other embodiments, the height and the width of the barrier 14 can be changed depending on different design specifications. The barrier 14 and the wall structure 15w of the lid 15 alone or together can prevent the light emitted by the light emitter 13 from directly transmitted to the light detector 11. For example, the light L14 passing through the gap between the wall structure 15w and the active surface 121 of the electronic component 12 can be blocked by the barrier 14. Compared to an optical device without the barrier 14 (only has a wall structure), the optical device 1 in FIG. 1A, which includes both the wall structure 15w and the barrier 14, has a better shielding ability, which can increase the signal-to-noise ratio (SNR) of the optical device 1. For example, the optical device without the barrier 14 has the SNR of 14, while the optical device 1 in FIG. 1A has the SNR of 316.

In some embodiments, the barrier 14 is disposed between the wall structure 15w and the active surface 121 of the electronic component 12 and is directly in contact with the wall structure 15w and the active surface 121 of the electronic component 12. However, during the process (e.g., reflow process) for manufacturing the optical device, as the temperature increases, the barrier 14 will expand. The expansion of the barrier 14 would compress the electronic component 12, rendering the electronic component 12 under stress, which may cause damage to the electronic component 12. In addition, since two spaces/cavities (one for accommodating the light emitter 13 and the other for accommodating the light detector 11) are completely separated or isolated by the wall structure 15w and the barrier 14, two vent holes are included for the cavities to avoid popcorn issue, which would increase the manufacturing cost and time.

In accordance with the embodiments as shown in FIG. 1A, since the lid 15 (or the wall structure 15w of the lid 15) is not in contact with either the barrier 14 or the electronic component 12, the barrier 14 and the wall structure 15w will not compress the electronic component 12 (e.g., stress free) during the high temperature process (e.g., reflow or curing process) for manufacturing the optical device 1, which can prevent the electronic component 12 from being cracked or damaged. In addition, since two cavities (one for accommodating the light emitter 13 and the other for accommodating the light detector 11) are connected to each other (e.g., are not completely sealed), solely one hole 10h is included to avoid popcorn issue, which can reduce the manufacturing cost and time.

The cover 17 is disposed on the lid 15. The cover 17 defines apertures 17h1 and 17h2. The lid 15 defines apertures 15h1 and 15h2. The apertures 17h1 and 15h1 are over the light detector 11. The apertures 17h2 and 15h2 are over the light emitter 13. The lens 16a is disposed within the apertures 17h1 and 15h1. The lens 16b is disposed within the apertures 17h2 and 15h2. The lenses 16a and 16b are arranged to allow the light (e.g., L11) emitted by the light emitter 13 and the light (e.g., L12) reflected by the object TB passing through. In some embodiments, the lenses 16a and 16b are plano-convex lenses, which can increase the density of the light and improve the performance of the optical device 1.

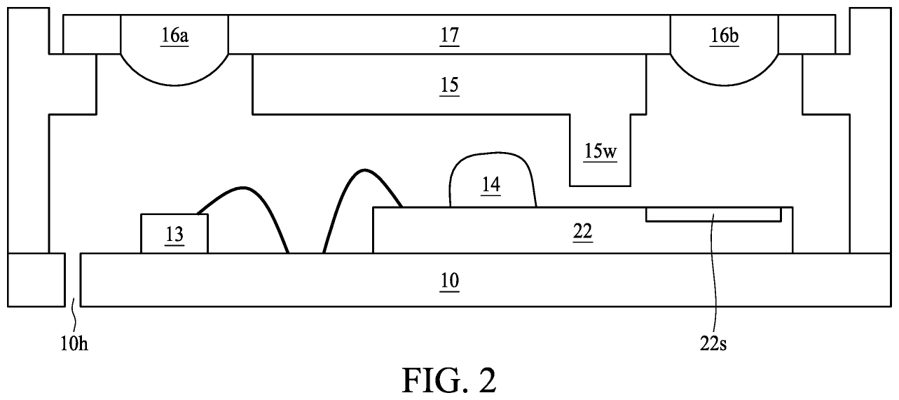

FIG. 2 illustrates a cross-sectional view of an optical device 2 in accordance with some embodiments of the present disclosure. The optical device 2 in FIG. 2 is similar to the optical device 1 in FIG. 1A, and the differences therebetween are described below.

As shown in FIG. 2, the light detector is integrated into an electronic component 22. For example, the electronic component 22 includes a sensing area 22s (or light detecting area) facing away from the substrate 10 (or facing toward the lens 16b) to receive the light. In some embodiments, the electronic component 22 may include a controller, a processor, a memory, an ASIC and the like. The light emitter 13 is disposed on the substrate 10 and spaced apart from the electronic component 22.

The wall structure 15w and the barrier 14 are disposed the light emitter 13 and the sensing area 22s of the electronic component 22. The barrier 14 is disposed between the light emitter 13 and the wall structure 15w. In some embodiments, the barrier 14 can be disposed between the wall structure 15w and the sensing area 22s of the electronic component 22. In some embodiments, the barrier 14 can be disposed at both sides of the wall structure 15w. For example, there are two barriers, one is disposed between the light emitter 13 and the wall structure 15w and the other is disposed between the wall structure 15w and the sensing area 22s of the electronic component 22.

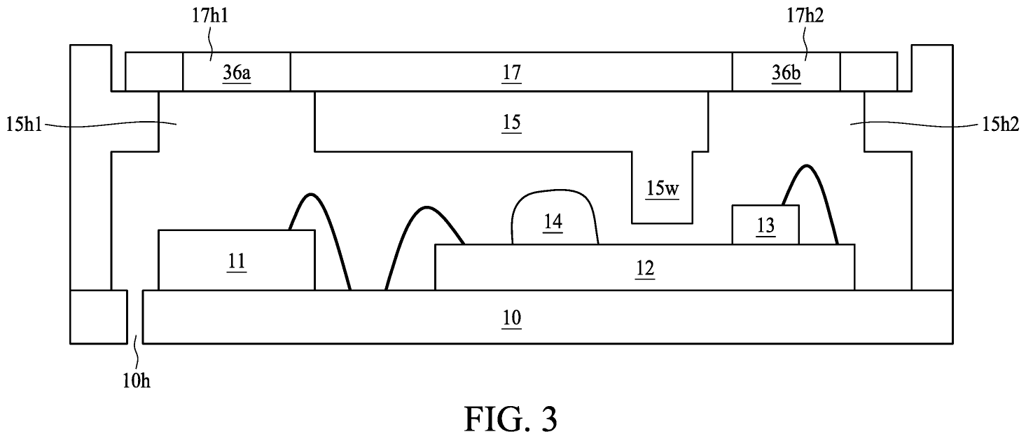

FIG. 3 illustrates a cross-sectional view of an optical device 3 in accordance with some embodiments of the present disclosure. The optical device 3 in FIG. 3 is similar to the optical device 1 in FIG. 1A, except that in the optical device 3, the lenses are replaced by flat transmissive films 36a and 36b.

The flat transmissive films 36a and 36b are respectively disposed within the apertures 17h1 and 17h2 defined by the cover 17. The flat transmissive films 36a and 36b are used to break up and evenly distribute light radiated toward light detector 11, which would enhance the uniformity of the light received by the light detector 11. In some embodiments, the flat transmissive films 36a and 36b are formed by dispensing transmissive gel within the apertures 17h1 and 17h2 or by transfer molding. In some embodiments, the flat transmissive films 36a and 36b may include a ground glass, Teflon, a holographic, an opal glass, and a greyed glass. In some embodiments, the flat transmissive films 36a and 36b may be formed of GaN or fused silica.

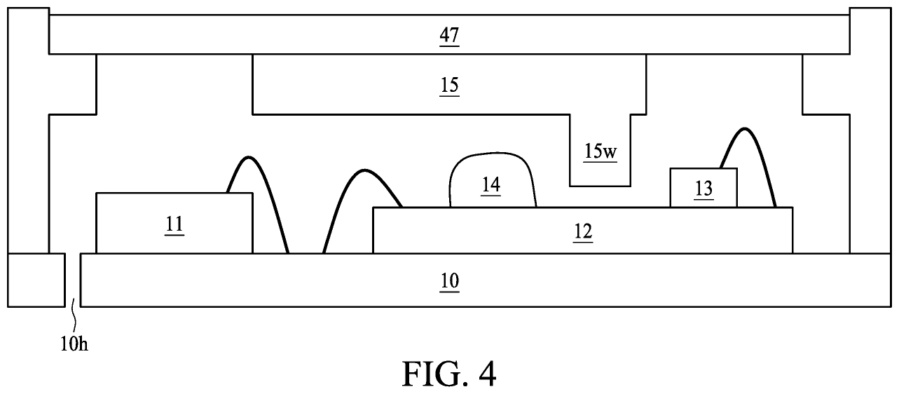

FIG. 4 illustrates a cross-sectional view of an optical device 4 in accordance with some embodiments of the present disclosure. The optical device 4 in FIG. 4 is similar to the optical device 1 in FIG. 1A except that a cover 47 in the optical device 4 is transparent to allow the light to pass through. In some embodiments, the cover 47 may include the material similar to the flat transmissive films 36a and 36b as shown in FIG. 3.

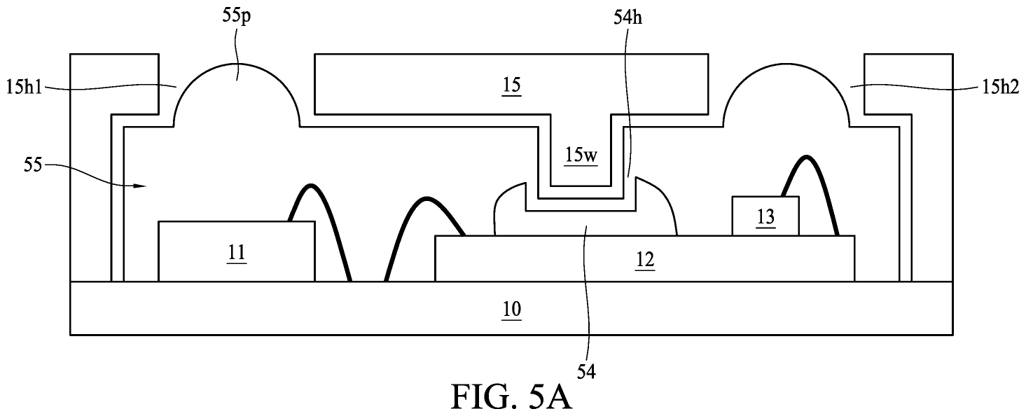

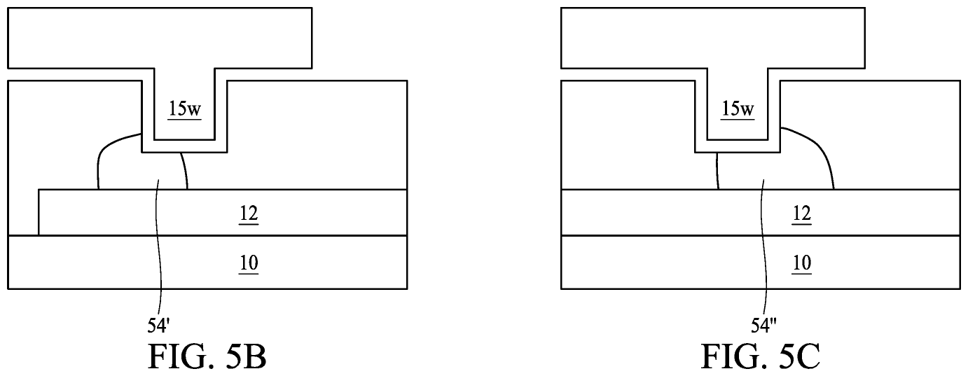

FIG. 5A illustrates a cross-sectional view of an optical device 5 in accordance with some embodiments of the present disclosure. The optical device 5 in FIG. 5A is similar to the optical device 1 in FIG. 1A, and the differences therebetween are described below.

The optical device 5 includes a barrier 54 (or dam) disposed between the wall structure 15w of the lid 15 and the electronic component 12. The barrier 54 has a recess 54h (opening or aperture). The wall structure 15w extends within the recess 54h of the barrier 54 without contacting the barrier 54. For example, the wall structure 15w is spaced apart from lateral surfaces and a bottom surface of the recess 54h. As shown in FIG. 5A, the barrier 54 may surround all the lateral surfaces of the wall structure 15w. In other embodiments, as shown in FIG. 5B and FIG. 5C, the barrier 54′, 54″ may only surround only a portion of the lateral surfaces of the wall structure 15w. For example, the barrier 54′ in FIG. 5B is located at only the left side of the wall structure 15w. For example, the barrier 54″ in FIG. 5C is located at only the right side of the wall structure 15w.

The optical device 5 may include a light transparent material 55 (e.g., a clear molding compound) disposed on the substrate 10 and covers the light detector 11, the electronic component 12, the light emitter 13 and the barrier 54. The light transparent material 55 covers the lateral surfaces and the bottom surface of the recess 54h of the barrier 54. The light transparent material 55 surrounds the wall structure 15w. The light transparent material 55 is spaced apart from the lid 15 (including the wall structure 15w). For example, there is a gap between the light transparent material 55 and the wall structure 15w. In some embodiments, the light transparent material 55 includes protrusion portions 55p extending within the apertures 15h1 and 15h2 of the lid 15. In some embodiments, the protrusion portions 55p may define plano-convex lenses, which can increase the density of the light and improve the performance of the optical device 5. In some embodiments, one of the protrusion portions 55p is located over the light detector 11 (e.g., over the light sensing area of the light detector 11), and the other one is located over the light emitter 13 (e.g., over the light emitting area of the light emitter 13).

Since the barrier 54 is disposed under the wall structure 15w of the lid 15, no further area on the electronic component 12 for placing the barrier 54 is included. Therefore, the barrier 54 in FIG. 5A may be applicable to an electronic component with a relatively smaller area or insufficient area for placing additional objects on its active surface.

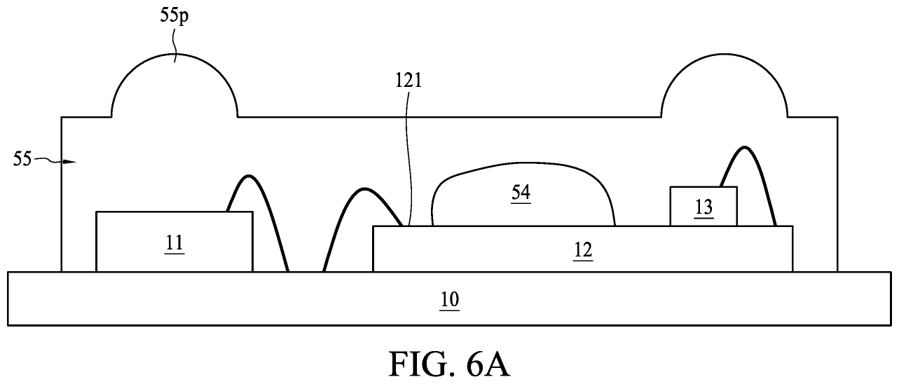

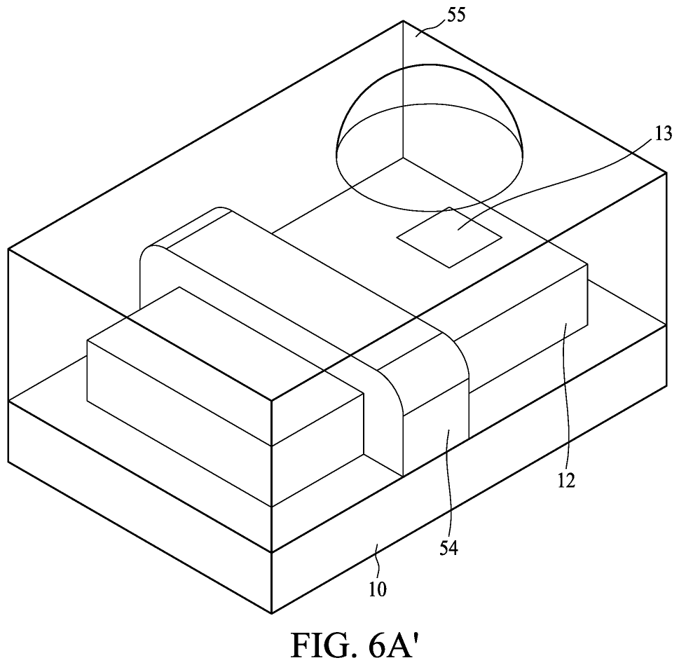

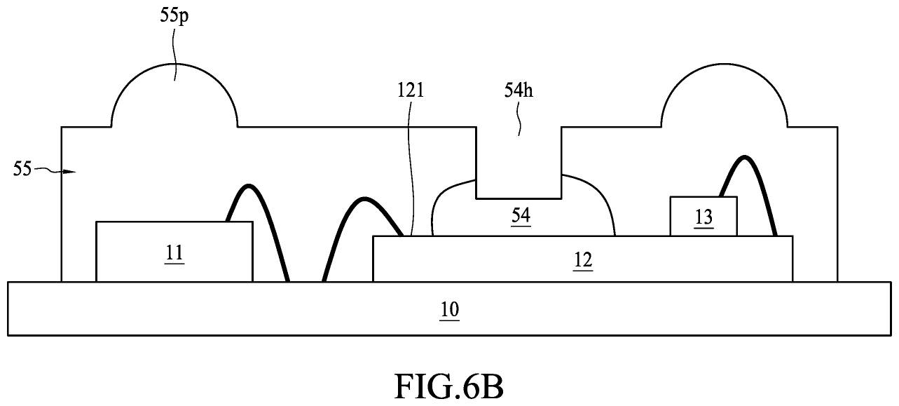

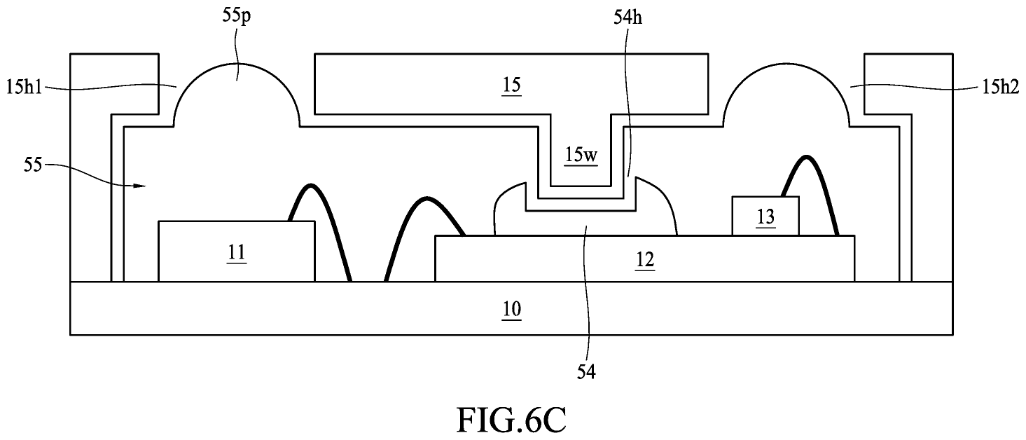

FIG. 6A, FIG. 6A′, FIG. 6B and FIG. 6C illustrate a method for manufacturing an optical device in accordance with some embodiments of the present disclosure. In some embodiments, the method illustrated in FIG. 6A, FIG. 6A′, FIG. 6B and FIG. 6C can be used to manufacture the optical device 5 as shown in FIG. 5A. Alternatively, the method illustrated in FIG. 6A, FIG. 6A′, FIG. 6B and FIG. 6C can be used to manufacture other optical devices.

Referring to FIG. 5A, the substrate 10 is provided. The light detector 11 and the electronic component 12 are disposed on the substrate 10 and connected to the substrate 10 by, for example, wire bonding technique or any other suitable techniques. The light emitter 13 is disposed on the active surface 121 of the electronic component 12. The barrier 54 is disposed on the active surface of the electronic component 12. The barrier 54 is disposed between the light detector 11 and the light emitter 13. The light transparent material 55 including the protrusion portions 55p is then formed on the substrate 10 to cover the light detector 11, the electronic component 12, the light emitter 13 and the barrier 54. In some embodiments, one of the protrusion portions 55p is located over the light detector 11 (e.g., over the light sensing area of the light detector 11), and the other one is located over the light emitter 13 (e.g., over the light emitting area of the light emitter 13). In some embodiments, the light transparent material 55 can be formed by molding technique (e.g., transfer molding, compression molding or the like) or any other suitable techniques.

In other embodiments, as shown in FIG. 6A′, which illustrates a perspective view of a portion of the structure in FIG. 6A, the barrier 54 can be also formed on lateral surfaces of the electronic component 12. For example, the barrier 54 covers the active surface and two lateral surfaces of the electronic component 12. For example, the barrier 54 is disposed across the electronic component 12.

Referring to FIG. 6B, a portion of the light transparent material 55 and the barrier 54 is removed to form the recess 54h. In some embodiments, the light transparent material 55 and the barrier 54 can be removed by, for example, routing, drilling, laser cutting or any other suitable processes.

Referring to FIG. 6C, the lid 15 is disposed on the substrate 10 while the wall structure 15w is disposed within the recess 54h to form the optical device 5 as illustrated in FIG. 5A. The lid 15 has apertures 15h1 and 15h2 to expose the protrusion portions 55p of the light transparent material 55.

As used herein, the terms “substantially,” “substantial,” “approximately,” and “about” are used to denote and account for small variations. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. As another example, a thickness of a film or a layer being “substantially uniform” can refer to a standard deviation of less than or equal to ±10% of an average thickness of the film or the layer, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within 50 μm of lying along a same plane, such as within 40 within 30 within 20 within 10 or within 1 μm of lying along the same plane. Two components can be deemed to be “substantially aligned” if, for example, the two components overlap or are within 200 within 150 within 100 within 50 within 40 within 30 within 20 within 10 or within 1 μm of overlapping. Two surfaces or components can be deemed to be “substantially perpendicular” if an angle therebetween is, for example, 90°±10°, such as ±5°, ±4°, ±3°, ±2°, ±1°, ±0.5°, ±0.1°, or ±0.05°. When used in conjunction with an event or circumstance, the terms “substantially,” “substantial,” “approximately,” and “about” can refer to instances in which the event or circumstance occurs precisely, as well as instances in which the event or circumstance occurs to a close approximation.

In the description of some embodiments, a component provided “on” another component can encompass cases where the former component is directly on (e.g., in physical contact with) the latter component, as well as cases where one or more intervening components are located between the former component and the latter component.

Additionally, amounts, ratios, and other numerical values are sometimes presented herein in a range format. It can be understood that such range formats are used for convenience and brevity, and should be understood flexibly to include not only numerical values explicitly specified as limits of a range, but also all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It can be clearly understood by those skilled in the art that various changes may be made, and equivalent elements may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. An optical device, comprising:
a substrate;
an electronic component disposed on the substrate, the electronic component having an active surface facing away from the substrate;
a lid disposed on the substrate, the lid having a wall structure extending toward the active surface of electronic component and spaced apart from the active surface of the electronic component; and
a barrier disposed on the active surface of the electronic component and spaced apart from the wall structure of the lid.

2. The optical device of claim 1, wherein a height of the barrier is equal to or greater than a distance between the wall structure and the active surface of the electronic component.

3. The optical device of claim 1, further comprising a light emitter disposed on the substrate, wherein
the electronic component has a light detecting area; and
the wall structure and the barrier are disposed between the light emitter and the light detecting area of the electronic component.

4. The optical device of claim 3, wherein the barrier is disposed between the light detecting area of the electronic component and the wall structure.

5. The optical device of claim 3, wherein the barrier is disposed between the light emitter and the wall structure.

6. The optical device of claim 3, wherein
the lid defines a first cavity accommodating the light detecting area and a second cavity accommodating the light emitter; and
the first cavity is connected to the second cavity.

7. The optical device of claim 6, wherein the electronic component has a first portion within the first cavity and a second portion within the second cavity.

8. An optical device, comprising:
a substrate;
an electronic component disposed on the substrate, the electronic component having an active surface facing away from the substrate;
a barrier disposed on the active surface of the electronic component; and
a lid disposed on the substrate, the lid having a wall structure extending toward the active surface of electronic component and spaced apart from the active surface of the electronic component,
wherein the barrier is spaced apart from the wall structure and adjacent to at least one lateral surface of the wall structure of the lid.

9. The optical device of claim 8, wherein the barrier surrounds all the lateral surfaces of the wall structure of the lid.

10. The optical device of claim 8, wherein at least one lateral surface of the wall structure of the lid faces away from the barrier.

11. The optical device of claim 8, wherein the barrier includes a recess and the wall structure of the lid extends within the recess.

12. The optical device of claim 8, further comprising:
a light detector disposed on the substrate; and
a light emitter disposed on the active surface of the electronic component, wherein
the wall structure and the barrier are disposed between the light emitter and the light detector.

13. The optical device of claim 12, further comprising a light transparent material disposed on the substrate and covering the barrier, the light detector and the light emitter, wherein the light transparent material is spaced apart from the lid.

14. The optical device of claim 12, wherein the light transparent material includes a first protrusion portion over the light emitter and a second protrusion portion over the light detector.

15. The optical device of claim 12, wherein the lid has a first aperture over the light emitter and a second aperture over the light detector.

16. A method for manufacturing an optical device, comprising:
(a) providing a substrate;
(b) disposing an electronic component on the substrate, the electronic component having an active surface facing away from the substrate;
(c) disposing a barrier on the active surface of the electronic component;
(d) removing a portion of the barrier to form a recess; and
(e) placing a lid disposed on the substrate, the lid having a wall structure extending within the recess and spaced apart from a sidewall and a bottom surface of the recess.

17. The method of claim 16, before operation (d) further comprising:
disposing a light detector on the substrate; and
disposing a light emitter on the active surface of the electronic component,
wherein the wall structure and the barrier are disposed between the light emitter and the light detector.

18. The method of claim 17, further comprising forming a light transparent material on the substrate to the barrier, the light detector and the light emitter.

19. The method of claim 18, wherein the light transparent material includes a first protrusion portion over the light emitter and a second protrusion portion over the light detector.

20. The method of claim 18, wherein operation (d) further comprises removing a portion of the light transparent material.
